(19) United States
(12) Patent Application Publication
(10) Pub. No.: US 2025/0201592 A1
(43) Pub. Date: Jun. 19, 2025

(54) SEMICONDUCTOR PROCESSING APPARATUS AND METHOD

(71) Applicant: HUAYING RESEARCH CO., LTD, Wuxi (CN)

(72) Inventors: Sophia Ziying WEN, Wuxi (CN); Dan ZHANG, Wuxi (CN)

(73) Assignee: HUAYING RESEARCH CO., LTD, Wuxi (CN)

(21) Appl. No.: 19/070,708

(22) Filed: Mar. 5, 2025

Related U.S. Application Data
(63) Continuation of application No. PCT/CN2023/073749, filed on Jan. 30, 2023.

(30) Foreign Application Priority Data
Sep. 9, 2022 (CN) 202211104708.2

(51) Int. Cl. H01L 21/67; H01L 21/3065

(52) U.S. Cl. CPC H01L 21/67069; H01L 21/6719; H01L 21/3065

(57) ABSTRACT

A semiconductor processing apparatus and a method, comprising: positioning a second chamber at an open position relative to a first chamber; positioning a semiconductor wafer to be processed between the first chamber and the second chamber; positioning the second chamber at a closed position relative to the first chamber; introducing an etching mixed gas into a sealed channel, wherein the etching mixed gas etches a partial surface of the semiconductor wafer, followed by discharging exhaust gas from the sealed channel; introducing a predetermined amount of extraction liquid into the sealed channel, wherein the extraction liquid is driven to flow through the sealed channel until exiting the sealed channel to extract metal contaminants. This method significantly reduces chemical consumption while improving etching depth precision, extraction solution control, etching uniformity, and surface roughness.

### CROSS-REFERENCE TO RELATED APPLICATIONS

This application is continuation of International Application No. PCT/CN2023/073749, filed on Jan. 30, 2023, which claims priority to Chinese Patent Application No. 202211104708.2, filed Sep. 9, 2022. The disclosures of the above-mentioned applications are hereby incorporated by reference in their entirety.

### FIELD OF THE INVENTION

The present disclosure relates to the field of surface processing for semiconductor wafers or similar workpieces, and more particularly, to a semiconductor processing apparatus and method.

### BACKGROUND

The processing of wafers can produce various metal contaminants. If these contaminants remain on the wafer, they may transform into trace amounts of metal ion contaminants, which can severely affect device lifespan, performance, and reliability due to their high mobility. Therefore, measuring metal contamination on wafer surfaces is critical in semiconductor device manufacturing. Currently, common metal analysis techniques typically involve Vapor Phase Decomposition (VPD) coupled with Inductively Coupled Plasma Mass Spectrometry (ICPMS).

The existing VPD technology only dissolves the natural oxide or thermally oxidized SiO2 surface layer of the wafer. Additionally, traditional chemical etching methods for metal analysis require large amounts of chemicals and may cause over-etching due to residual chemical liquids.

Thus, it is necessary to propose a new solution to solve these issues.

### SUMMARY

The present disclosure provides a semiconductor processing apparatus and method that significantly reduces chemical consumption for bulk metal detection while enabling precise control over etching area, depth, surface roughness, and uniformity. To achieve this, in one aspect, a semiconductor processing apparatus is provided, comprising: a first chamber; and a second chamber movable relative to the first chamber between an open position and a closed position, wherein when the second chamber is at the closed position relative to the first chamber, a micro chamber is formed between the first chamber and the second chamber, and a semiconductor wafer to be processed can be accommodated in the micro chamber, and when the second chamber is at the open position relative to the first chamber, the semiconductor wafer to be processed can be taken out of or put into the micro chamber; the first chamber and/or the second chamber comprises a recessed groove formed on a recessed inner wall surface facing the micro chamber, wherein when the second chamber is at the closed position relative to the first chamber and the semiconductor wafer is accommodated in the micro chamber, one surface of the semiconductor wafer abuts against an inner wall surface of the recessed groove formed by the first chamber and the second chamber, thereby forming a sealed channel between the recessed groove and the semiconductor wafer surface. An etching operation is performed by introducing an etching mixed gas into the sealed channel wherein the etching mixed gas flows through the sealed channel to etch a partial surface of the semiconductor wafer facing the sealed channel, followed by using gas or liquid to discharge residual reaction gas and reaction product gas from the sealed channel. The steps are repeated to increase etching depth. An extraction operation is performed by introducing a predetermined amount of extraction liquid into the sealed channel, wherein the extraction liquid is driven by gas to flow through the channel until exiting, thereby extracting metal contaminants from the partial surface of the semiconductor wafer facing the sealed channel.

According to another aspect, the present disclosure provides a semiconductor processing method using the apparatus, comprising: positioning the second chamber at the open position relative to the first chamber; placing the semiconductor wafer to be processed between the first chamber and the second chamber; positioning the second chamber at the closed position relative to the first chamber; an etching operation is performed by introducing an etching mixed gas into the sealed channel wherein the etching mixed gas flows through the sealed channel to etch a partial surface of the semiconductor wafer facing the sealed channel, followed by using gas or liquid to discharge residual reaction gas and reaction product gas from the sealed channel; an extraction operation is performed by introducing a predetermined amount of extraction liquid into the sealed channel, wherein the extraction liquid is driven by gas to flow through the channel until exiting, thereby extracting metal contaminants from the partial surface of the semiconductor wafer facing the sealed channel.

Compared to existing techniques, the present disclosure comprises a recessed groove formed on an inner wall surface of a chamber, which creates a sealed channel by utilizing the barrier formed by the semiconductor wafer to be processed, while the chemical fluids flows within the sealed channel, the surface of the semiconductor wafer can be simultaneously processed, allowing precise control of surface etching while significantly reduces chemical consumption. Additionally, the present discourse can use etching mixed gas instead of liquid to perform etching operations, allowing for better control of etching and extraction, the volume of extraction solution accurately, and achieves precise quantitative detection. The method can avoid problems associated with existing chemical etching methods, such as surface roughness caused by residual chemicals and difficulties in precise control of the extraction solution quality.

### BRIEF DESCRIPTION OF THE DRAWINGS

The present disclosure may be better understood by referring to the drawings as well as the detailed description below. In particular, same numerals are used to refer to same structural parts throughout the drawings, and wherein:

FIG. 1a illustrates a cross-section view of a schematic diagram of a semiconductor process apparatus of the present disclosure, according to one embodiment.

FIG. 1b illustrates an enlarged schematic diagram of a circle A shown in FIG. 1a

FIG. 1c illustrates an enlarged schematic diagram of a circle B shown in FIG. 1a.

FIG. 2a illustrates a top view of a lower chamber, according to one embodiment.

FIG. 2b illustrates an enlarged schematic diagram of a circle C shown in FIG. 2a.

FIG. 2c illustrates an enlarged schematic diagram of a circle D shown in FIG. 2a.

FIG. 2d illustrates a cross-section view of a schematic diagram of a lower chamber shown in FIG. 2a.

FIG. 2e illustrates an enlarged schematic diagram of a circle E shown in FIG. 2d.

FIG. 2f illustrates an enlarged schematic diagram of a circle F shown in FIG. 2a.

FIG. 3a illustrates a top view of an upper chamber, according to one embodiment of the present disclosure.

FIG. 3b illustrates an enlarged schematic diagram of a circle G shown in FIG. 3a.

FIG. 3c illustrates an enlarged schematic diagram of a circle H shown in FIG. 3a.

FIG. 3d illustrates a cross-section view of a schematic diagram of a upper chamber shown in FIG. 3a.

FIG. 3e illustrates an enlarged schematic diagram of a circle I shown in FIG. 3d.

FIG. 3f illustrates an enlarged schematic diagram of a circle J shown in FIG. 3a.

FIG. 4a illustrates a cross-section view of a schematic diagram of a semiconductor process apparatus of the present disclosure, according to another embodiment.

FIG. 4b illustrates an enlarged schematic diagram of a circle K shown in FIG. 4a.

FIG. 5a illustrates a top view of an upper chamber, according to one embodiment.

FIG. 5b illustrates a cross-section view of the semiconductor wafer along a section line C-C of FIG. 5a.

FIG. 5c illustrates an enlarged schematic diagram of a circle L shown in FIG. 5c.

FIG. 6a illustrates a top view of a lower chamber, according to another embodiment of the present disclosure.

FIG. 6b illustrates an enlarged schematic diagram of a circle M shown in FIG. 6a.

FIG. 7 is a flowchart of a semiconductor processing method according to one embodiment of the present disclosure.

### DETAILED DESCRIPTION OF THE PREFERRED EMBODIMENTS

To make the objectives, features, and advantages of the present disclosure more comprehensible, the following provides a detailed description of the embodiments with reference to the accompanying drawings.

The term ‘one embodiment’ or ‘embodiment’ referred to here refers to specific features, structures, or characteristics related to the embodiment that can be included in at least one implementation of the present disclosure. The phrase “in one embodiment” appearing in different places in this instruction does not necessarily refer to the same embodiment, nor does it necessarily mean a separate or alternative embodiment that is mutually exclusive with other embodiments. In the present disclosure, “multiple” and “several” refer to two or more. In the present disclosure, “and/or” represents “and” or “or”.

The present disclosure proposes a semiconductor processing apparatus that precisely controls the flow direction and speed of the processing fluids while significantly reducing the processing fluids consumption.

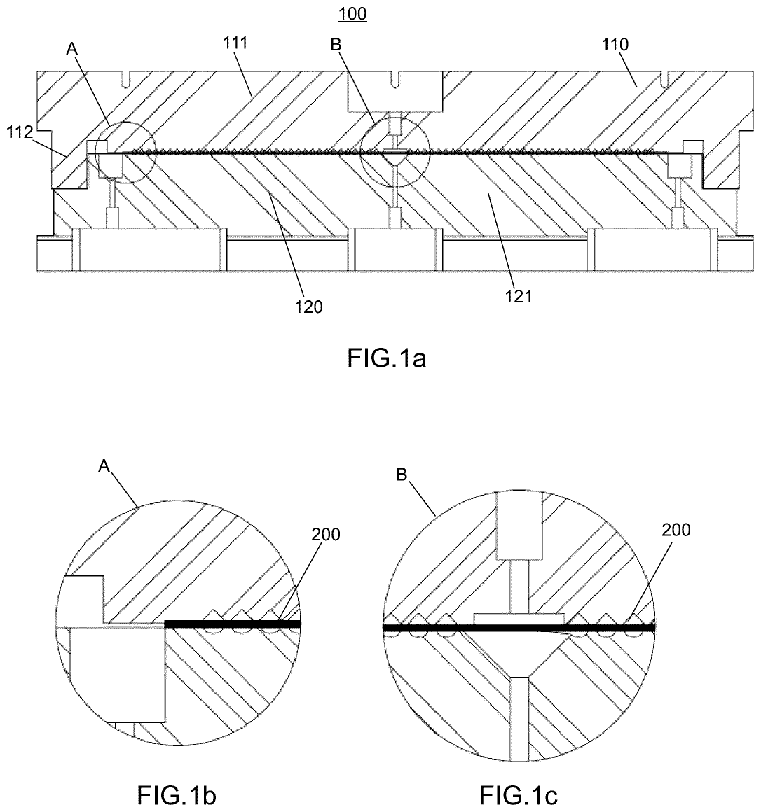

FIG. 1a illustrates a cross-section view of a schematic diagram of a semiconductor process apparatus 100, according to one embodiment. FIG. 1b illustrates an enlarged schematic diagram of a circle A shown in FIG. 1a; FIG. 1c illustrates an enlarged schematic diagram of a circle B shown in FIG. 1a. As shown in FIG. 1a, the semiconductor processing apparatus 100 includes an upper chamber 110 and a lower chamber 120.

The upper chamber 110 comprises an upper chamber board 111 and a first protruding edge 112 extended downward from the periphery of the upper chamber board. The lower chamber 120 comprises a lower chamber board 121 and a first groove 122 that dented downward at the periphery of the lower chamber board 121.

The upper chamber 110 is movable relative to the lower chamber 120 between an open position and a closed position. When the upper chamber 110 is at the open position relative to the lower chamber 120, a semiconductor wafer to be processed can be placed on or taken out of an inner wall surface of the lower chamber 120. When the upper chamber 110 is at the closed position relative to the lower chamber 120, the first protruding edge 112 cooperates with the first groove 122 to form a sealed micro chamber between the upper and lower chamber boards, accommodating the semiconductor wafer for subsequent process.

One of the upper chamber 110 and the lower chamber 120 may be referred to as the first chamber, and the other of the upper chamber 110 or the lower chamber 120 may be referred to as the second chamber. The motion of the upper chamber 110 and the lower chamber 120 is relative, either by moving the upper chamber 110 to cause the upper chamber 110 to move relative to the lower chamber 120, or by moving the lower chamber 120 to cause the upper chamber 110 to move relative to the lower chamber 120.

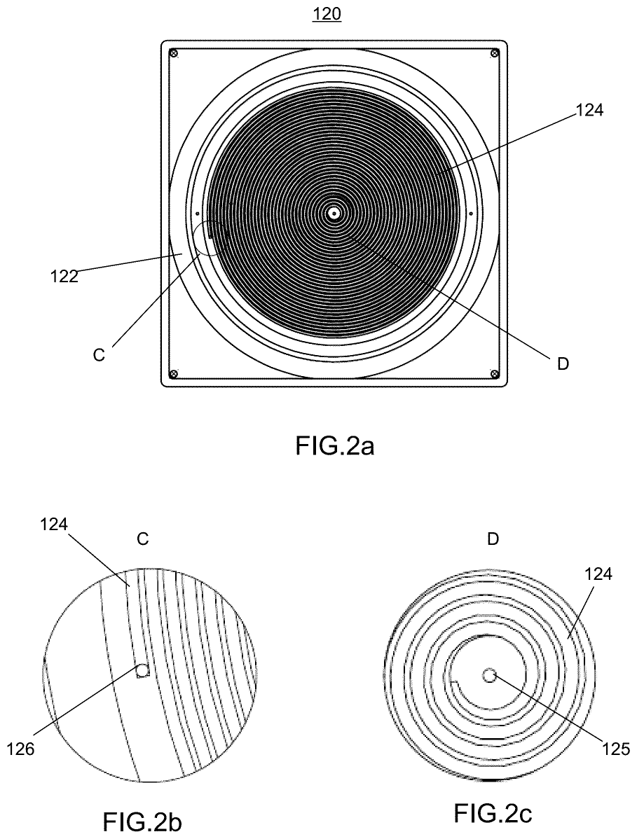

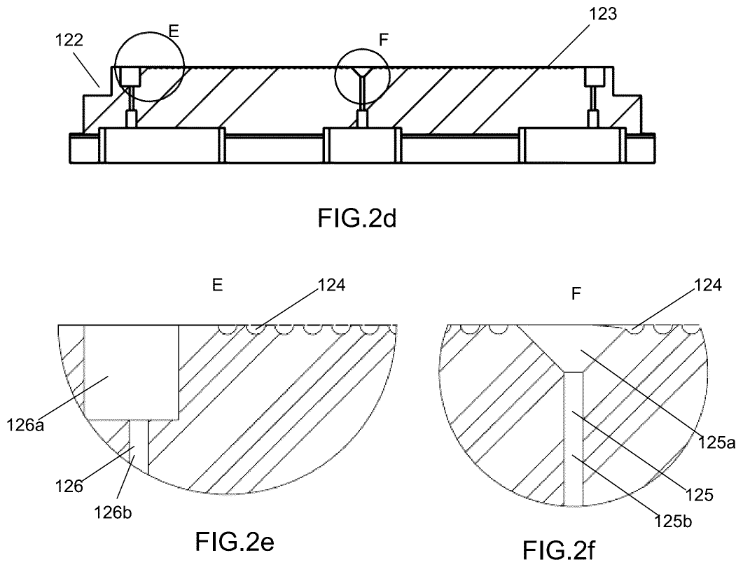

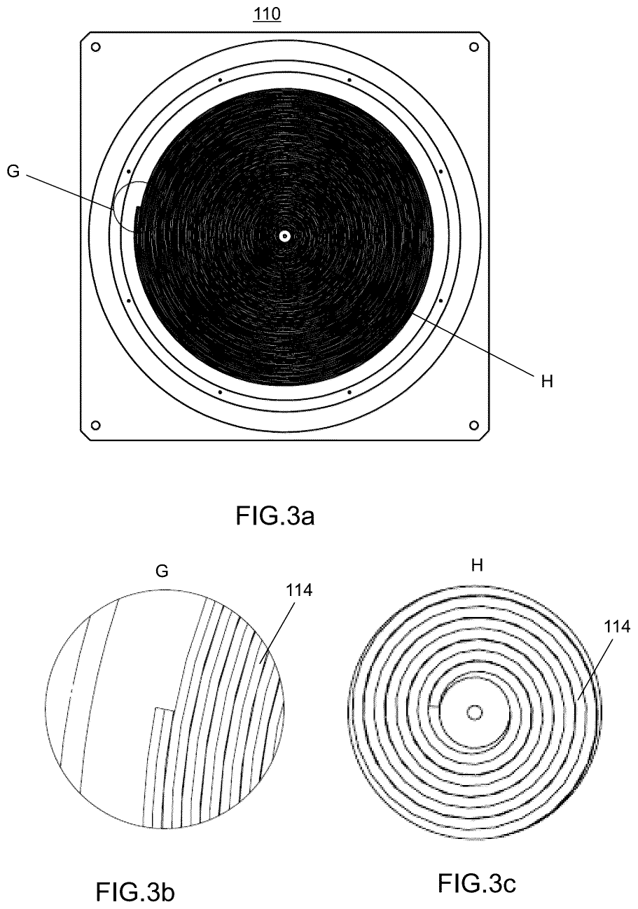

FIG. 2a illustrates a top view of a lower chamber 120, according to one embodiment. FIG. 2b illustrates an enlarged schematic diagram of a circle C shown in FIG. 2a. FIG. 2c illustrates an enlarged schematic diagram of a circle D shown in FIG. 2a. FIG. 2d illustrates a cross-section view of a schematic diagram of a lower chamber shown in FIG. 2a. FIG. 2e illustrates an enlarged schematic diagram of a circle E shown in FIG. 2d. FIG. 2f illustrates an enlarged schematic diagram of a circle F shown in FIG. 2a.

As shown in FIGS. 2a-2f, the lower chamber 120 comprises a recessed groove 124 formed on a inner wall surface 123 facing the micro chamber, a first through-hole 125 penetrating from the exterior of the lower chamber to connect with a first position of the recessed groove 124, and a second through-hole 126 penetrating from the exterior of the lower chamber to connect with a second position of the recessed groove 124. The cross-section of the recessed groove 124 may be U-shaped, V-shaped, semicircular, or other shapes. The number of through-holes in the recessed groove 124 may be one or more.

In another embodiment, each recessed groove 124 may correspond to multiple through-holes. The recessed groove 124 is divided into multiple segments by the multiple through-holes, with each groove segment having one through-hole at each end for connection.

As shown in FIGS. 1a, 1b, and 1c, when the upper chamber 110 is at the closed position relative to the lower chamber 120 and the semiconductor wafer 200 is accommodated in the micro chamber, a surface (lower surface) of the semiconductor wafer 200 abuts against the inner wall surface 123 forming the recessed groove 124. The recessed groove 124 and the surface of the semiconductor wafer 200 thereby form a sealed channel, which connects with the exterior through the first through-hole 125 and the second through-hole 126. During operation, a processing fluid enters the sealed channel through the first through-hole 125, flows along the channel, contacts and processes a partial area of the semiconductor wafer 200, and exits through the second through-hole 126 for extraction. In this way, not only can the flow direction and flow speed of the processing fluid be precisely controlled, but the consumption of the processing fluid can also be greatly reduced.

In one embodiment, as shown in FIGS. 2a, 2b, and 2c, the recessed groove 124 rings and forms a spiral shape. The first through-hole 125 is located at the central region (area circled as D) of the spiral groove, and the second through-hole 126 is located at the peripheral region (area circled as C) of the spiral groove 124. The first through-hole 125 may serve as an inlet, while the second through-hole 126 serves as an outlet. In other embodiments, the first through-hole 125 may serve as an outlet, while the second through-hole 126 serves as an inlet.

In one embodiment, as shown in FIGS. 2d, 2e, and 2f, the first through-hole 125 comprises a first buffer port 125a which directly connected to the recessed groove 124 and is deeper and wider than the recessed groove 124, and a first through-hole port 125b connected to the first buffer port 125a. The first buffer port 125a can prevent over-treating the central area of the semiconductor wafer from excessive initial flow velocity of the processing fluid. The second through-hole 126 comprises a second buffer port 126a which is directly connected to the recessed groove 124 and is deeper and wider than the recessed groove 124, and a first through-hole port 126b connected to the first buffer port 126a. The second buffer port 126a can prevent the processing fluid overflow from the second through-hole 126 due to delayed discharge through the second through-hole 126. Preferably, the first buffer port 125a may be a tapered recess, while the second buffer port 126a may be a cylindrical recess.

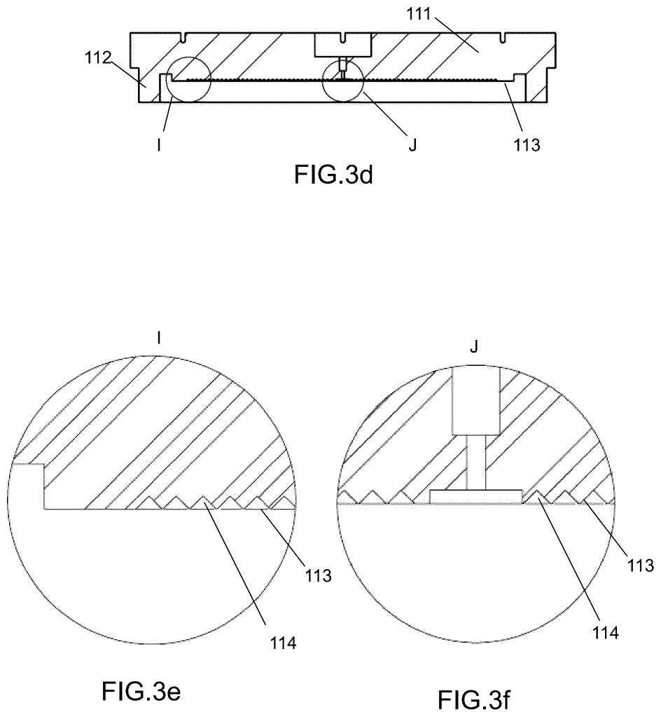

FIG. 3a illustrates a top view of a upper chamber 110, according to one embodiment of the present disclosure; FIG. 3b illustrates an enlarged schematic diagram of a circle G shown in FIG. 3a; FIG. 3c illustrates an enlarged schematic diagram of a circle H shown in FIG. 3a; FIG. 3d illustrates a cross-section view of a schematic diagram of a lower chamber shown in FIG. 3a; FIG. 3e illustrates an enlarged schematic diagram of a circle I shown in FIG. 3d; FIG. 3f illustrates an enlarged schematic diagram of a circle J shown in FIG. 3a.

As shown in FIGS. 3a-3f, the upper chamber 110 comprises an upper chamber board 111 and a first protruding edge 112 extended downward from the periphery of the upper chamber board 111. The upper chamber 110 comprises a recessed groove 113 formed on a recessed inner wall surface 123 facing the micro chamber. The groove walls (portions between adjacent the recessed groove 114) of the recessed groove 114 which is formed on the inner wall surface 113 of the upper chamber 110, align with (FIGS. 1b, 1c) the groove walls (portions between adjacent the recessed groove 124) of the recessed groove 124 which is formed on the inner wall surface 123 of the lower chamber 120. In this way, when the upper chamber 110 is at the closed position relative to the lower chamber 120 and the semiconductor wafer 200 is accommodated in the micro chamber, the groove walls of the recessed groove 114 of the upper chamber 110 may be abutted against corresponding positions of the semiconductor wafer 200, ensuring tighter contact with the groove walls of the recessed groove 124 of the lower chamber 120. This enhances the sealing performance of the final formed sealed channel. Additionally, the groove walls (portions between adjacent the recessed groove 114) of the recessed groove 114 formed on an inner wall surface 123 of the upper chamber and the groove walls (portions between adjacent the recessed groove 124) of the recessed groove 124 formed on an inner wall surface 123 of the lower chamber 120 may be arranged in an alternating pattern.

In another modified embodiment, the structures of the upper chamber 110 and the lower chamber may be interchangeable or identical. In this case, the upper surface of the semiconductor wafer 200 forms a sealed channel with the recessed groove of the upper chamber 110. Processing fluid flowing through the sealed channel can process the upper surface or lower surface, or both surfaces at the same time of the semiconductor wafer 200 to be processed.

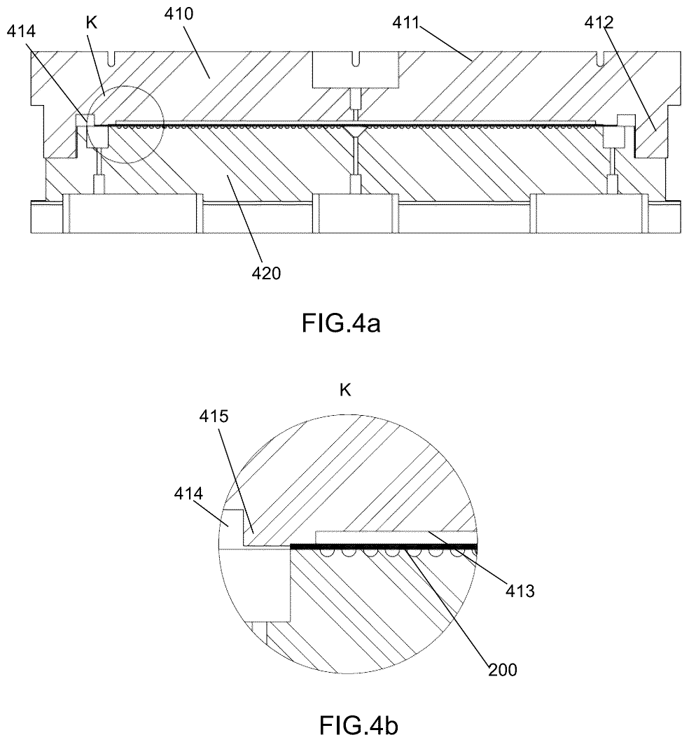

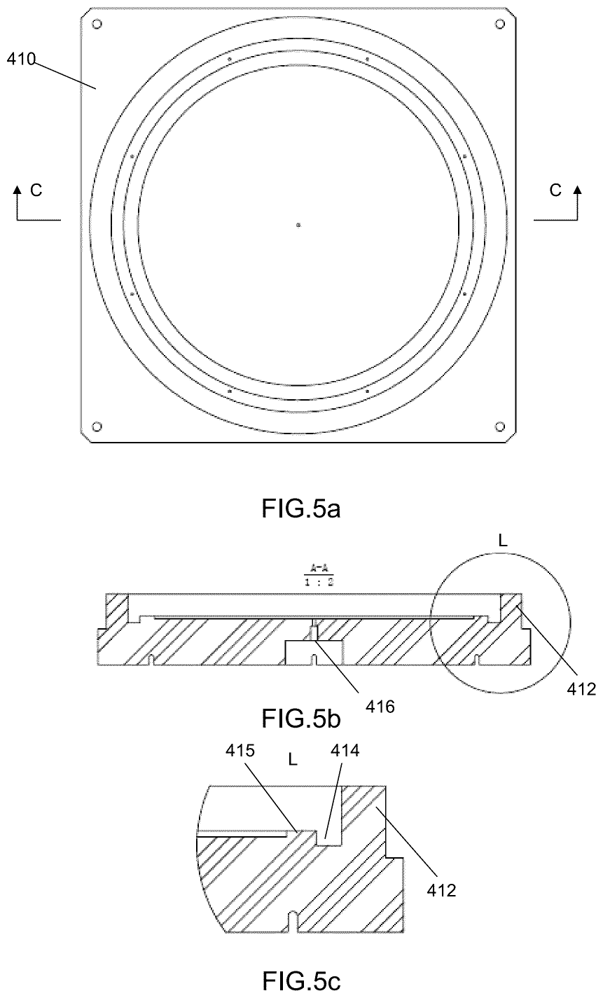

FIG. 4a illustrates a cross-section view of a schematic diagram of a semiconductor process apparatus, according to another embodiment. FIG. 4b illustrates an enlarged schematic diagram of a circle K shown in FIG. 4a. The difference between the apparatus 400 in FIG. 4a and the apparatus in FIG. 1a is that the structure of the upper chamber 410 in FIG. 4a differs from the structure of the upper chamber 110 in FIG. 1a. FIG. 5a illustrates a top view of an upper chamber 410, according to one embodiment. FIG. 5b illustrates a cross-section view of the semiconductor wafer along a direction C-C of FIG. 5a. FIG. 5c illustrates an enlarged schematic diagram of a circle L shown in FIG. 5c. As shown in FIGS. 5a-5c, the upper chamber 410 comprises an upper chamber board 411, a first protruding edge 412, a first inner wall surface 413 facing the micro chamber, a second recessed groove 414, a second protruding edge 415 between the first inner wall surface 413 and the second recessed groove 414, and a passage 416 at the center of the first inner wall surface 413. The second protruding edge 415 abuts against the semiconductor wafer 200 and the first inner wall surface 413 to form a sealed space, which connects with the exterior through the passage 416. Fluid entering the sealed space through the passage 416 generates pressure, pressing the semiconductor wafer 200 tightly against the groove walls of the recessed groove 124 of the lower chamber 120, thereby improving the sealing performance of the final formed sealed channel.

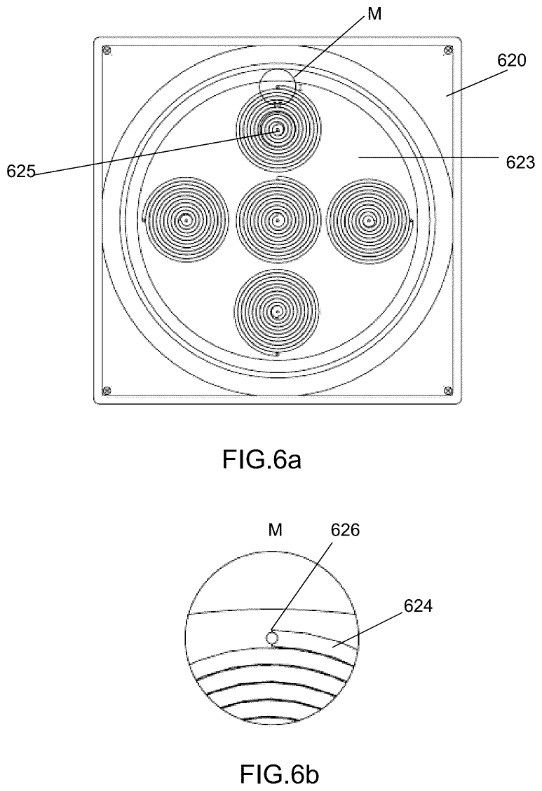

FIG. 6a illustrates a top view of a lower chamber 620, according to another embodiment of the present disclosure. FIG. 6b illustrates an enlarged schematic diagram of a circle M shown in FIG. 6a. The recessed grooves 624 formed on the recessed inner wall surface 623 of the lower chamber 620 facing the micro chamber are multiple. There are five recessed grooves in FIG. 6a, while in other embodiments, it may be other numbers. Each recessed groove 624 corresponds to a first through-hole 625 and a second through-hole 626. The different recessed grooves 624 are distributed in different regions of the inner wall surface 623, which allows for different operations to be performed to different regions, which are independent of each other.

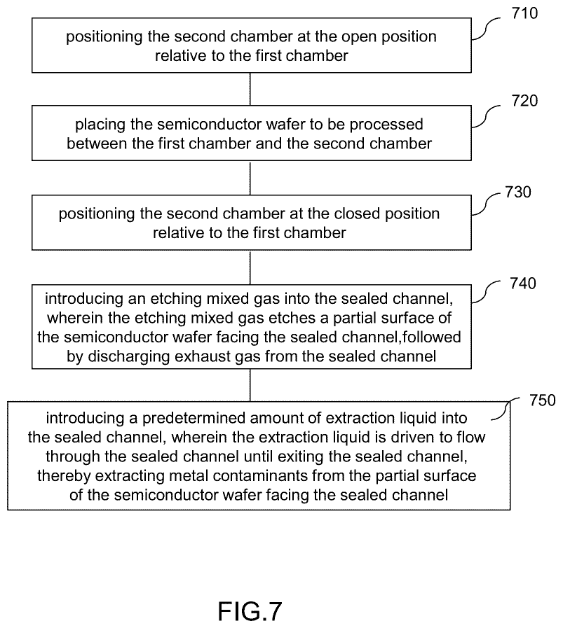

The present disclosure also proposes a semiconductor processing method using the aforementioned apparatus. As shown in FIG. 7, the semiconductor processing method 700 comprises the following steps:

Step 710: Position the second chamber at the open position relative to the first chamber.

Step 720: Place the semiconductor wafer to be processed between the first chamber and the second chamber.

Step 730: Position the second chamber at the closed position relative to the first chamber.

Step 740: Perform the etching operation: introduce an etching mixed gas into the sealed channel. The gas flows through the channel and etches a partial surface of the semiconductor wafer facing the channel, followed by using gas or liquid to discharge residual reaction gas and product gas. The residual reaction gas and product gas can be referred to as exhaust gas.

The etching mixed gas comprises one or more etching gases which is one or more of hydrofluoric acid gas and nitric acid gas. The etching mixed gas further comprises ozone or a carrier gas, wherein the carrier gas is one or more of nitrogen gas and inert gas.

In one embodiment, the etching mixed gas includes two types: a first etching mixed gas formed by introducing ozone into an etching liquid, resulting in a mixed gas comprising the etching gas and ozone. A second etching mixed gas is formed when a carrier gas into an etching liquid, resulting in a mixed gas comprising the etching gas and carrier gas. The etching gas may also be referred to as etching vapor, such as hydrogen fluoride vapor or nitric acid vapor.

In a preferred embodiment, the etching operation cyclically alternates between the first etching step and the second etching step. The first etching step introduces a first etching mixed gas containing etching gas and ozone into the sealed channel for a first predetermined period. The second etching step introduces a second etching mixed gas containing etching gas and carrier gas into the sealed channel for a second predetermined period. In one embodiment, the first predetermined period is 20 seconds, while the second predetermined period is 10 seconds, then repeat this cycle 22 times. Be more specific, during the second step, the first etching mixed gas remains in the channel, and the etching gas of the second etching mixed gas enters into the channel through diffusion.

In a specific embodiment, the etching principle is:

O3+Si=SiO2+O2SiO2+4HF=SiF4+2H2O.

In the first etching step, ozone reacts with silicon on the wafer surface to form silicon dioxide, and hydrofluoric acid gas reacts with silicon dioxide to form silicon tetrafluoride, so that it can etch a certain depth of the silicon layer. Metal impurities on the original silicon surface and within the reaction layer remain on the wafer surface. In the second etching step, excess ozone is neutralized by additional hydrofluoric acid gas. In one embodiment, the etching rate is approximately 1-6 μm/H.

During the etching operation, the flow direction of the etching mixed gas in the sealed channel may be continuously altered. This controls the etching depth by adjusting reaction time and gas flow direction.

After cycling the first and second etching steps, the etching operation further includes continuously purging the sealed channel with the second etching mixed gas for a third predetermined period to further etch silicon oxides on the wafer surface.

After utilizing the second etching mixed gas to continuously flow through the sealed channel for the third predetermined period, the etching operation further includes continuously purging the sealed channel with the carrier gas for the fourth predetermined period to discharge residual reaction gas and reaction product gas. Alternatively, liquid may be used to discharge residual reaction gas and reaction product gas.

Step 750: Perform the extraction operation: introduce a predetermined amount of extraction liquid into the sealed channel, wherein the extraction liquid is driven to flow through the sealed channel until exiting the sealed channel, thereby extracting metal contaminants from the partial surface of the semiconductor wafer facing the sealed channel. To be specific, when the extraction liquid is driven to flow through the sealed channel, it chemically reacts with metal contaminants on the wafer surface to dissolve them into the solution.

As the extraction liquid flows on the surface of a semiconductor wafer, it collects metal contaminants from all contacted areas. The extraction liquid is then transferred from the wafer surface to a sample vial. The extraction liquid is driven to flow by a driving gas, wherein the driving gas is one or more of nitrogen gas and inert gas. The extraction liquid may contain nitric acid, HF, hydrogen peroxide, or a combination thereof.

In a preferred embodiment, the sealed channel is arranged in a spiral shape. Each recessed groove is divided into segments by through-holes, with each groove segment having one through-hole at each end for connection, forming multiple sealed channel segments. In one embodiment, etching and extraction can be performed on each sealed channel segment separately, or etching and extraction can be performed jointly on multiple sealed channel segments.

Compared to existing technologies, the present disclosure offers one or more of the following advantages:

1. Etching and extraction are performed in the same chamber, avoiding cross-contamination from wafer movement

2. The spiral structure of the micro chamber maximizes the utilization efficiency of reaction gases.

3. Etching the semiconductor wafer through etching gases flowing through the sealed channel significantly reduces chemical consumption. Furthermore, gas etching enables immediate termination of chemical reactions, thereby avoiding over-etching issues caused by residual chemical liquids in traditional wet etching methods.

4. The process generates no water or liquid waste, drastically reducing pollutant discharge and associated treatment costs.

5. The etching depth can be precisely controlled.

6. Reaction speed is controllable by modulating gas pressure to regulate gas concentration, mixing ratios, and flow velocity within the reaction chamber.

7. The minimal volume of extraction liquid required drastically lowers chemical usage. Moreover, the reduced liquid volume results in a significantly higher concentration of metal contaminants in the extraction solution under identical contamination levels compared to conventional large-volume extraction liquid methods, thereby substantially improving metal detection rate.

8. The method enables precise control over the etched area, depth, surface roughness, and uniformity of the etched surface.

The above description fully discloses the embodiments of the present disclosure. It should be noted that any modifications made by those skilled in the art without departing from the scope of the claims are within the protection of the present disclosure. Accordingly, the scope of the claims is not limited to the described embodiments.

What is claimed is:

1. A semiconductor processing apparatus, comprising:
a first chamber; and
a second chamber movable relative to the first chamber between an open position and a closed position, wherein when the second chamber is at the closed position relative to the first chamber, a micro chamber is formed between the first chamber and the second chamber, and a semiconductor wafer to be processed can be accommodated in the micro chamber; when the second chamber is at the open position relative to the first chamber, the semiconductor wafer to be processed can be taken out of or put into the micro chamber;
wherein at least one of the first chamber or the second chamber comprises a recessed groove formed on a recessed inner wall surface facing the micro chamber, when the second chamber is at the closed position relative to the first chamber and the semiconductor wafer is accommodated in the micro chamber, at least one surface of the semiconductor wafer abuts on an inner wall surface where the recessed groove formed, such that the recessed groove and the surface of the semiconductor wafer form a sealed channel;
performing an etching operation, comprising: introducing an etching mixed gas into the sealed channel, when the etching mixed gas flows through the sealed channel to etch a partial surface of the semiconductor wafer facing the sealed channel, followed by using gas or liquid to discharge residual reaction gas and reaction product gas from the sealed channel;
performing an extraction operation, comprising: introducing a predetermined amount of extraction liquid into the sealed channel, when the extraction liquid is driven to flow through the sealed channel and chemically reacts with metal contaminants remaining on the surface of the wafer, dissolving the contaminants into the extraction liquid until the extraction liquid exits the sealed channel, thereby extracting metal contaminants from the partial surface of the semiconductor wafer facing the sealed channel.

2. The semiconductor processing apparatus according to claim 1, wherein:
the etching mixed gas comprises an etching gas, which is one or more of hydrofluoric acid gas and nitric acid gas;
the etching mixed gas further comprises ozone or a carrier gas, wherein the carrier gas is one or more of nitrogen gas and inert gas;
the extraction liquid is driven to flow by a driving gas, wherein the driving gas is one or more of nitrogen gas and inert gas.

3. The semiconductor processing apparatus according to claim 2, wherein:
the etching mixed gas is formed by introducing ozone or carrier gas into an etching liquid, resulting in a mixed gas comprising the etching gas and ozone, or a mixed gas comprising the etching gas and carrier gas.

4. The semiconductor processing apparatus according to claim 2, wherein the etching operation cyclically alternates between a first etching step and a second etching step, wherein: in the first etching step, a first etching mixed gas comprising the etching gas and ozone is introduced into the sealed channel and maintained for a first predetermined period; in the second etching step, a second etching mixed gas comprising the etching gas and carrier gas is introduced into the sealed channel and maintained for a second predetermined period.

5. The semiconductor processing apparatus according to claim 4, wherein during the second etching step, the first etching mixed gas remains in the sealed channel, and the etching gas in the second etching mixed gas entered the sealed channel through diffusion.

6. The semiconductor processing apparatus according to claim 1, wherein during the etching operation, the flow direction of the etching mixed gas in the sealed channel is continuously altered.

7. The semiconductor processing apparatus according to claim 1, wherein at least one of the first chamber or the second chamber further comprises a first through-hole penetrating from an exterior of the first chamber and/or the second chamber to connect with a first position of the recessed groove; a second through-hole penetrating from the exterior of the first chamber and/or the second chamber to connect with a second position of the recessed groove, the sealed channel connects with the exterior through the first through-hole and the second through-hole, wherein one of the first through-hole and the second through-hole serves as a fluid inlet of the sealed channel, and the other serves as a fluid outlet of the sealed channel.

8. The semiconductor processing apparatus according to claim 7, wherein the recessed groove rings and forms a spiral shape.

9. The semiconductor processing apparatus according to claim 1, wherein the recessed grooves formed on the recessed inner wall surface of the first chamber facing the micro chamber are multiple; each recessed groove has a first through-hole and a second through-hole correspondingly, thereby forming multiple sealed channels, wherein the etching operation for each sealed channel is performed independently.

10. A semiconductor processing method using the semiconductor processing apparatus, the apparatus comprising: a first chamber; a second chamber movable relative to the first chamber between an open position and a closed position, wherein the second chamber is at the closed position relative to the first chamber, a micro chamber is formed between the first chamber and the second chamber, and a semiconductor wafer to be processed can be accommodated in the micro chamber, and wherein the second chamber is at the open position relative to the first chamber, the semiconductor wafer to be processed can be taken out of or put into the micro chamber; at least one of the first chamber or the second chamber comprises a recessed groove formed on a recessed inner wall surface facing the micro chamber, wherein when the second chamber is at the closed position relative to the first chamber and the semiconductor wafer is accommodated in the micro chamber, at least one surface of the semiconductor wafer abuts on an inner wall surface where the recessed groove formed, such that the recessed groove and the surface of the semiconductor wafer form a sealed channel, the method comprising:
positioning the second chamber at the open position relative to the first chamber;
placing the semiconductor wafer to be processed between the first chamber and the second chamber;
positioning the second chamber at the closed position relative to the first chamber;
performing an etching operation: introducing an etching mixed gas into the sealed channel, wherein the etching mixed gas etches a partial surface of the semiconductor wafer facing the sealed channel, followed by discharging exhaust gas from the sealed channel; and
performing an extraction operation: introducing a predetermined amount of extraction liquid into the sealed channel, wherein the extraction liquid is driven to flow through the sealed channel until exiting the sealed channel, thereby extracting metal contaminants from the partial surface of the semiconductor wafer facing the sealed channel.
